(19) United States
(12) Patent Application Publication
(10) Pub. No.: US 2013/0043492 A1
(43) Pub. Date: Feb. 21, 2013

(54) NITRIDE SEMICONDUCTOR TRANSISTOR

(71) Applicant: Panasonic Corporation, Osaka (JP)

(72) Inventors: Toshiyuki TAKIZAWA, Kyoto (JP); Tetsuzo UEDA, Osaka (JP)

(73) Assignee: PANASONIC CORPORATION, Osaka (JP)

(21) Appl. No.: 13/658,598

(22) Filed: Oct. 23, 2012

Related U.S. Application Data
(63) Continuation of application No. PCT/JP2010/006941, filed on Nov. 29, 2010.

(30) Foreign Application Priority Data
Apr. 28, 2010 (JP) 2010-103460

(51) Int. Cl. H01L 29/778

(52) U.S. Cl. 257/77; 257/194; 257/E29.246

(57) ABSTRACT

A nitride semiconductor transistor includes a heterojunction layer including a plurality of nitride semiconductor layers having different polarizations, and a gate electrode disposed on the heterojunction layer. An electron current reduction layer having a p-type conductivity is disposed between the heterojunction layer and the gate electrode to pass hole current therethrough and reduce electron current.

### CROSS-REFERENCE TO RELATED APPLICATIONS

This is a continuation of PCT International Application PCT/JP2010/006941 filed on Nov. 29, 2010, which claims priority to Japanese Patent Application No. 2010-103460 filed on Apr. 28, 2010. The disclosures of these applications including the specifications, the drawings, and the claims are hereby incorporated by reference in their entirety.

### BACKGROUND

The present disclosure relates to nitride semiconductor transistors.

Group III nitride semiconductors (hereinafter abbreviated as nitride semiconductors) represented by gallium nitride (GaN) have better physical properties, i.e., a wider band gap and a higher breakdown field, than silicon (Si) and gallium arsenic (GaAs), and have been expected as a new material for use in high power transistors. The band gap of each of nitride semiconductors can be freely changed by changing the ratio between or among elements of the nitride semiconductor. For example, in an AlGaN/GaN heterostructure obtained by joining nitride semiconductor layers of AlGaN and GaN having different band gaps, charge is generated at the heterojunction interface on a (0001) crystal plane due to spontaneous polarization and piezoelectric polarization, and even if the layers are undoped, a sheet carrier concentration of 1×10¹³ cm⁻² or higher can be obtained. Therefore, in particular, a heterojunction electric field effect transistor (HFET) utilizing the charge generated at the heterojunction interface as a channel has been actively researched and developed, because the HFET can achieve a high current density, and thus, can provide higher power.

The inventors of the present disclosure have proposed and are developing a gate injection transistor (GIT) in which holes are injected from a gate electrode into a channel, and which can further drive drain current (see, e.g., Japanese Patent Publication No. 2006-339561). The GIT has a structure including a p-type layer for injecting holes into a gate of a usual HFET structure. Operation of the GIT will be described hereinafter. First, in a first stage, drain current starts flowing by application of gate voltage which hardly causes gate current to flow. With a further increase in the gate voltage, holes flow from a p-type layer immediately below the gate electrode into the channel. This provides recombination of electrons in the channel and the injected holes, and in a second stage, the drain current increases. After these two stages, the GIT can achieve high drain current drive characteristics.

### SUMMARY

However, in terms of the operation principle of the GIT, gate current flows into the GIT, and thus, losses are always caused by current components of the gate current. The current components through the gate electrode include hole current and electron current. The GIT controls electron current toward a drain electrode by allowing hole current to flow from the gate electrode. However, due to high electron mobility, a portion of the electron current flows into the gate electrode, and so-called overflow occurs. The overflow is directly linked to power losses. Therefore, while electron current is reduced as much as possible, hole current needs to be increased.

In order to reduce electron current, the conduction band offset of the p-type layer may be increased as much as possible. GaN is usually used as a material of the p-type layer; however, when, e.g., AlGaN or AlN is used thereas, this can significantly reduce electron current. However, AlGaN and AlN have a very low activation rate of holes. Thus, with an increase in the Al content in the p-type layer, the activation rate sharply decreases, resulting in a significant increase in gate drive voltage. Therefore, it is not easy to replace the p-type layer with, e.g., AlGaN.

An object of the present disclosure is to solve the above problem, and provide a nitride semiconductor transistor with reduced power loss.

In order to achieve the above object, the present disclosure provides a nitride semiconductor transistor including an electron current reduction layer of a multiple quantum barrier structure.

Specifically, a nitride semiconductor transistor of the present disclosure includes: a heterojunction layer including two or more nitride semiconductor layers having different polarizations; a gate electrode disposed on the heterojunction layer; and an electron current reduction layer disposed between the heterojunction layer and the gate electrode, having a p-type conductivity, and configured to pass hole current and reduce electron current.

The nitride semiconductor transistor of the present disclosure allows injection of holes into a channel formed in the heterojunction layer, and can reduce electron current arising from overflow. This can reduce gate current, thereby significantly reducing the power loss in the nitride semiconductor transistor.

In the nitride semiconductor transistor of the present disclosure, the electron current reduction layer may be a multilayer structure including a plurality of layers having different polarizations. In this case, the plurality of layers may be each made of a nitride semiconductor containing at least one of boron, aluminum, gallium, or indium. The plurality of layers preferably have random thicknesses.

The nitride semiconductor transistor of the present disclosure may further include: a contact layer disposed between the electron current reduction layer and the gate electrode, and containing a higher concentration of a p-type impurity than other layers.

The nitride semiconductor transistor of the present disclosure may further include: source and drain electrodes formed laterally outward of the gate electrode.

In the nitride semiconductor transistor of the present disclosure, the heterojunction layer may be disposed on a substrate, and the substrate may be a silicon substrate, a sapphire substrate, or a silicon carbide substrate.

The nitride semiconductor transistor of the present disclosure can reduce power loss.

### BRIEF DESCRIPTION OF THE DRAWINGS

FIG. 1 is a graph illustrating results of determining the relationships between gate voltage and gate current and between the gate voltage and drain current through simulation.

FIG. 2 is a cross-sectional view illustrating the structure of a transistor for explaining the relationship between the gate current and the drain current.

FIG. 3 is a diagram illustrating the potential of a multiple quantum barrier (MQB) structure.

FIG. 4 is a graph illustrating a result of determining reflection of electron waves on the MQB structure by calculation.

FIG. 5 is a diagram illustrating the potential of an electron current reduction layer including constituent layers with different thicknesses.

FIG. 6 is a diagram illustrating the potential of the electron current reduction layer including the constituent layers with different compositions.

FIG. 7 is a graph illustrating a result of determining reflection of electron waves on the electron current reduction layer including constituent layers with different thicknesses by calculation.

FIG. 8 is a graph illustrating a result of determining reflection of electron waves on the electron current reduction layer including the constituent layers with different compositions by calculation.

FIG. 9 is a diagram illustrating the potential of a gate of a nitride semiconductor transistor using a p-type GaN layer.

FIG. 10 is a diagram illustrating the potential of a gate of a nitride semiconductor transistor using a current reduction layer.

FIGS. 11A-11D are cross-sectional views sequentially illustrating process steps in a method for fabricating a nitride semiconductor transistor according to an embodiment.

FIG. 12 is a graph illustrating operating characteristics of a conventional nitride semiconductor transistor.

FIG. 13 is a graph illustrating operating characteristics of a nitride semiconductor transistor according to an embodiment.

### DETAILED DESCRIPTION

### Principle

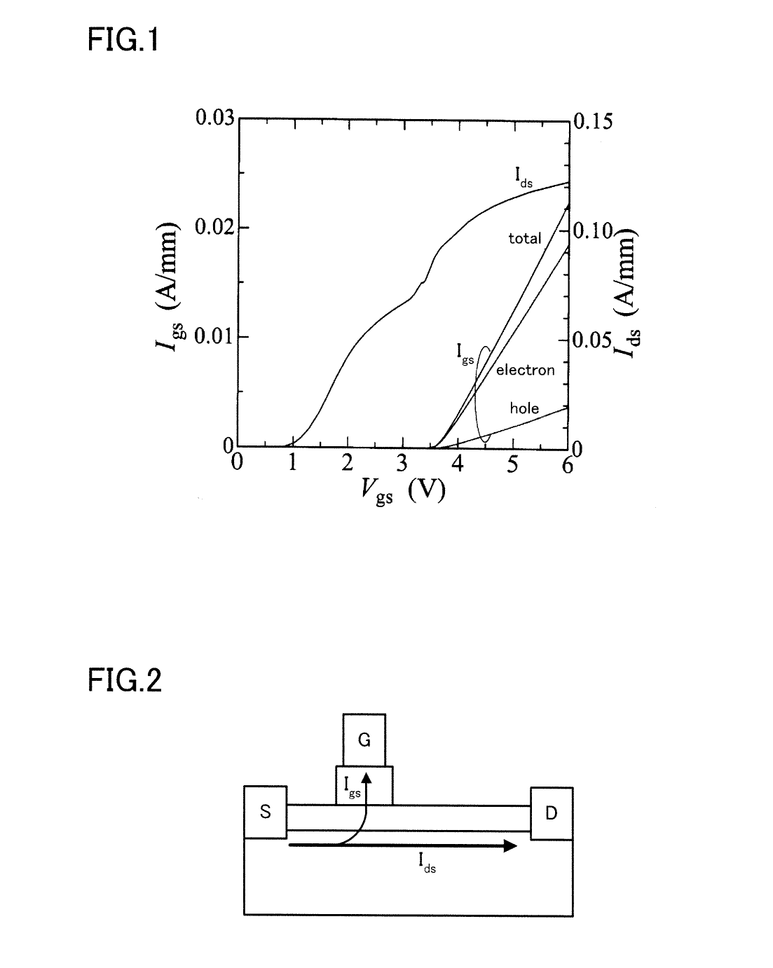

First, a principle for reducing the power loss of a GIT which is a nitride semiconductor transistor will be described. FIG. 1 illustrates results of calculating the gate current Igs and the drain current Ids using a device simulator when the gate voltage Vgs is varied in a positive direction. A device for use in the calculation included a 2-μm-thick GaN layer, a 25-nm-thick AlGaN layer, and a 200-nm-thick p-GaN layer which were sequentially formed, and a source electrode, a gate electrode, and a drain electrode which were formed on the p-GaN layer. The Al content in the AlGaN layer was assumed to be 25%, and the concentration of holes in the p-GaN layer was assumed to be 1×18 cm⁻³. The spacing between the source electrode and the gate electrode was 4 μm, and the spacing between the drain electrode and the gate electrode was 10 μm. The source electrode and the drain electrode were in ohmic contact with a two-dimensional electron gas (2DEG) layer induced immediately below the AlGaN layer. In the calculation, the drain-to-source voltage Vds was 1 V, and the electron mobility and the hole mobility in the p-GaN layer were 1000 cm²/Vs and 10 cm²/Vs, respectively.

As illustrated in FIG. 1, when the gate voltage Vgs is 0 V, neither of the gate current Igs and the drain current Ids flows. When the gate voltage Vgs exceeds 1 V, the drain current Ids starts flowing. The reason for this is that application of the gate voltage Vgs reduces the band energy level immediately below the gate, thereby generating electrons at the AlGaN/GaN interface. In this case, no gate current Igs flows. Thereafter, with an increase in the gate voltage Vgs, the drain current Ids gradually increases. When the gate voltage Vgs is higher than about 3 V, the drain current Ids significantly increases, and the gate current Igs also starts flowing. The reason for this is as follows: holes are injected from the gate electrode into the 2DEG layer, the holes are recombined with the electrons, and this recombination acts like priming, resulting in a further increase in the drain current Ids. As such, a feature of the GIT structure is that the current injection effect arising from application of the gate voltage Vgs significantly increases the drain current Ids.

The gate current includes hole current and electron current. As illustrated in FIG. 1, the ratio of electron current to hole current is very high, and the electron current makes up the majority of the gate current. As illustrated in FIG. 2, the electron current is originally produced by so-called overflow in which a portion of current which should flow from a source electrode S to a drain electrode D flows toward a gate electrode G. Therefore, the flow of the electron current denotes that a power loss is occurring. For example, when the gate voltage Vgs is 6 V, the drain current Ids is about seven times the gate current Igs. This means that in terms of a bipolar transistor, the current amplification factor hFE is 7, and such a transistor is not so efficient. An alternative view is that about 13% of the original drain current Ids is changed to gate current, and thus, a power loss is occurring.

A task for a conventional GIT using a p-type GaN layer as a gate as described above is to reduce electron current, and in particular, when the GIT is driven at high current, an especially significant problem is caused. In order to achieve a structure reducing electron current, the inventors of the present disclosure focused attention on a multiple quantum barrier (MQB) structure. The MQB structure is a periodic structure in which a heterojunction is formed between or among two or more materials, and in which band discontinuity occurs. When electrons pass through a heterojunction interface at which band discontinuity occurs, some of the electrons are always reflected. This phenomenon is caused also when electrons have higher kinetic energy than a barrier between two layers forming the MQB structure. A structure in which reflection of electron waves is intentionally utilized by using a multilayer periodic structure to prevent transmission of electron waves is the MQB structure.

In order to allow electron waves to be efficiently reflected by the MQB structure, the size of the MQB structure needs to be smaller than the length through which electrons can ballistically move. Specifically, the size of the MQB structure needs to be smaller than the coherence length of electrons. The coherence length of electrons can be easily calculated from the product of the electron mobility, an electric field, and the electron-electron scattering lifetime. When the electron mobility is 1000 cm²/Vs, an electric field of 1V is applied to a thickness range of 100-200 nm, and the electron-electron scattering lifetime is 0.1 psec, the coherence length of electrons is 50-100 nm. Therefore, when a multiple quantum barrier is formed within the above thickness range, the multiple quantum barrier is expected to sufficiently function as an electron wave reflector.

Therefore, when, instead of the p-type GaN layer, the MQB structure is used as the gate of the GIT, it is expected that overflow can be reduced. In order to use the MQB structure as the gate of the GIT, the MQB structure needs to allow electrical conduction similarly to the p-type GaN layer without functioning as a barrier to holes. When the hole coherence length is estimated in a manner similar to the manner in which the electron coherence length is estimated, the hole coherence length is 1 nm at a standard hole mobility of 10 cm²/Vs. For this reason, holes classically behave in response to a barrier with a thickness exceeding 1 nm, and thus, multiple interferences hardly occur. Therefore, the influence of interference effects of the MQB structure on hole conduction can be ignored.

The valence band offset is smaller than the conduction band offset. However, conduction of holes may be blocked to some extent. In contrast, when a biaxial strain occurs, the valence band offset is much smaller than when no strain occurs. The reason for this is that a valence band is formed by a club-shaped p orbital. When a strain is applied to the nitride semiconductor, the energy levels of three valence bands increase or decrease depending on a combination of the orientations of p orbitals and the direction of the strain. In particular, when AlGaN having a smaller lattice constant than GaN is on GaN having a (0001) plane as a principal surface, a tensile biaxial strain is applied in an in-plane direction. In this case, among the three valence bands, a heavy hole band and a light hole band shift in directions in which the corresponding energy levels increase, and a crystal-field split-off hole band shifts in a direction in which the corresponding energy level decreases. This allows the heavy hole band and the light hole band to shift in directions in which the corresponding valence band offsets are canceled as compared with when no strain occurs. In contrast, a conduction band is formed mainly by an s orbital which is symmetrical with respect to a point, and thus, even with a biaxial strain, the lower conduction band edge uniformly changes. However, such a significant change that completely cancels a large conduction band offset does not occur.

The MQB structure having a polarization further has an advantage for conduction of holes. Bands of each of the layers of the MQB structure having a polarization are tilted by an internal electric field. Holes bound to acceptors are localized around an accepter element unless energy, such as heat, is applied to the holes. When a host material has an internal electric field, an electric field is applied also to acceptors and holes. In this case, the acceptors are attracted to positive potential, and the holes are attracted to negative potential, thereby dissociating the acceptors from the holes with lower heat energy than usual. This can enhance the activation rate of holes by polarization. Therefore, the use of the MQB structure can further improve electrical conduction of holes.

When the MQB structure is used as the gate of the GIT using a nitride semiconductor, not only a transistor body, but also the MQB structure is preferably made of a nitride semiconductor. In this case, the nitride semiconductor preferably contains at least one of boron (B), aluminum (Al), gallium (Ga), or indium (In) as a Group III element. The conduction band offset of a nitride semiconductor is much larger than the valence band offset thereof, and the conduction band offsets of, e.g., AlGaN and GaN are three times as large as the valence band offsets thereof. The reason for this is that the valence band is comprised mainly of a highly localized orbital of nitrogen. Therefore, even with a small compositional modulation, the conduction band offset can be more significantly changed than the valence band offset.

As described above, the MQB structure using a nitride semiconductor has the following two features. First, wave interference effects allow efficient reflection of electron waves, and can prevent passage of electron current through the MQB structure. The MQB structure is a system in which the conduction band offset is especially large, and thus, even with a small compositional modulation, the advantages of the MQB structure are significant. Next, holes are neither interfered with nor reflected by the MQB structure, and when a biaxial strain occurs, the valence band offset can be reduced. Furthermore, polarization can enhance the activation rate of holes.

In order to examine the effect of reducing electron current through the gate by the MQB structure, calculations of reflection of electron waves by the MQB structure were performed. The calculations were based on, for example, a MQB structure including 2-nm-thick AlGaN layers having an Al content of 20%, and 8-nm-thick GaN layers. When the Al content is 20%, the conduction band offset of AlGaN relative to GaN is 0.3 eV, and the valence band offset is merely 80 meV. The number of pairs of AlGaN and GaN layers is eight, and the total thickness of the AlGaN layers and the total thickness of the GaN layers are 16 nm and 64 nm, respectively. If the MQB structure were an AlGaN layer of uniform composition, the Al content would be 4% which is an average value. The conduction band offset of the AlGaN layer having an Al content of 4% is merely 60 meV, and thus, it is anticipated that the AlGaN layer will fail to function as a barrier to electron current.

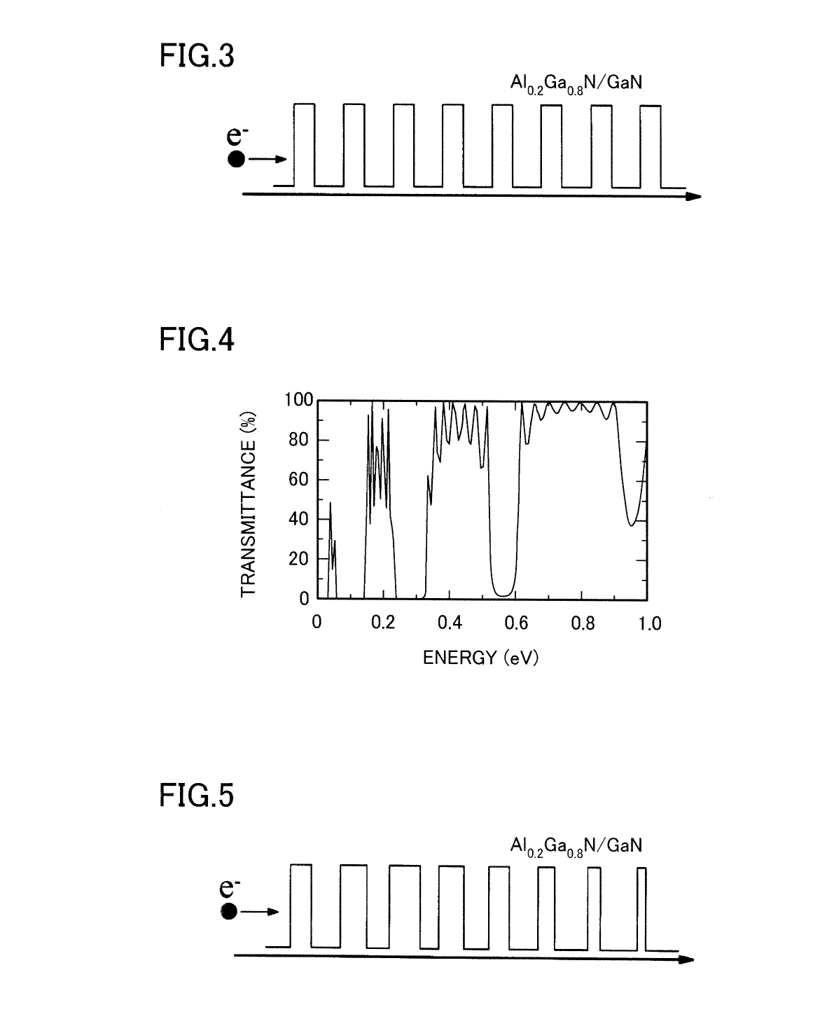

FIG. 3 schematically illustrates the potential of the MQB structure model used for the calculations. In FIG. 3, the thickness of each of the AlGaN layers and the thickness of each of the GaN layers are 2 nm and 8 nm, respectively. When electron waves having various kinetic energies enter such an MQB structure model, the proportion of some of the electron waves reflected by the MQB structure model was calculated by a transfer matrix method. Specifically, the proportion was calculated under the conditions where the amplitudes of electron waves are continuously connected together at the potential boundaries, and the amplitude differentials thereof are also continuously connected together at the potential boundaries.

FIG. 4 illustrates calculation results. In FIG. 4, the abscissa represents the kinetic energy of electrons. When the MQB structure is not present, and electron waves enter a bulk GaN layer, an electron kinetic energy higher than or equal to 0 eV allows the transmittance of the electron waves through the bulk GaN layer to be always 100%. As illustrated in FIG. 4, when the MQB structure is used, this significantly reduces transmission of electron waves. The reason for this is that electron waves are reflected by a potential change at the heterojunction interface. However, when, in FIG. 4, the kinetic energy is 0.2 eV, and is in the range of 0.4-0.5 eV, the transmittance is increased. This increase is due to resonance tunneling. Coupling between the quantized level of each of the GaN layers and an adjacent level increases the transmittance at certain energies.

As such, also within the range of very high energies, electron waves can be reflected with higher reflectivity by the MQB structure than by a barrier formed by a layer with an average composition. However, due to the periodicity of the MQB structure, the transmittances of electron waves having specific kinetic energies are increased.

In order to prevent the transmittances of electron waves having specific kinetic energies from increasing, an electron current reduction structure in which the periodicity is intentionally broken is studied. In the electron current reduction structure, an intentional break in the potential periodicity is expected to prevent coupling between the energy level formed in each of layers with low potential energy and the energy level of an adjacent layer. Parameters for determining energy levels are the thickness, potential, and effective mass of each of layers. When electrons are in the conduction band, it is difficult to significantly modulate the effective mass without changing the compositions of constituent elements. The reason for this is that an electron wave derivative at the lower conduction band edge is spherically symmetrical, and even with application of a strain, the wave function does not change much. Furthermore, the potential energy also significantly depends on the compositions of the constituent elements. Therefore, when the electron current reduction structure is made of a nitride semiconductor, the compositions and layer thicknesses serve as mainly adjustable parameters.

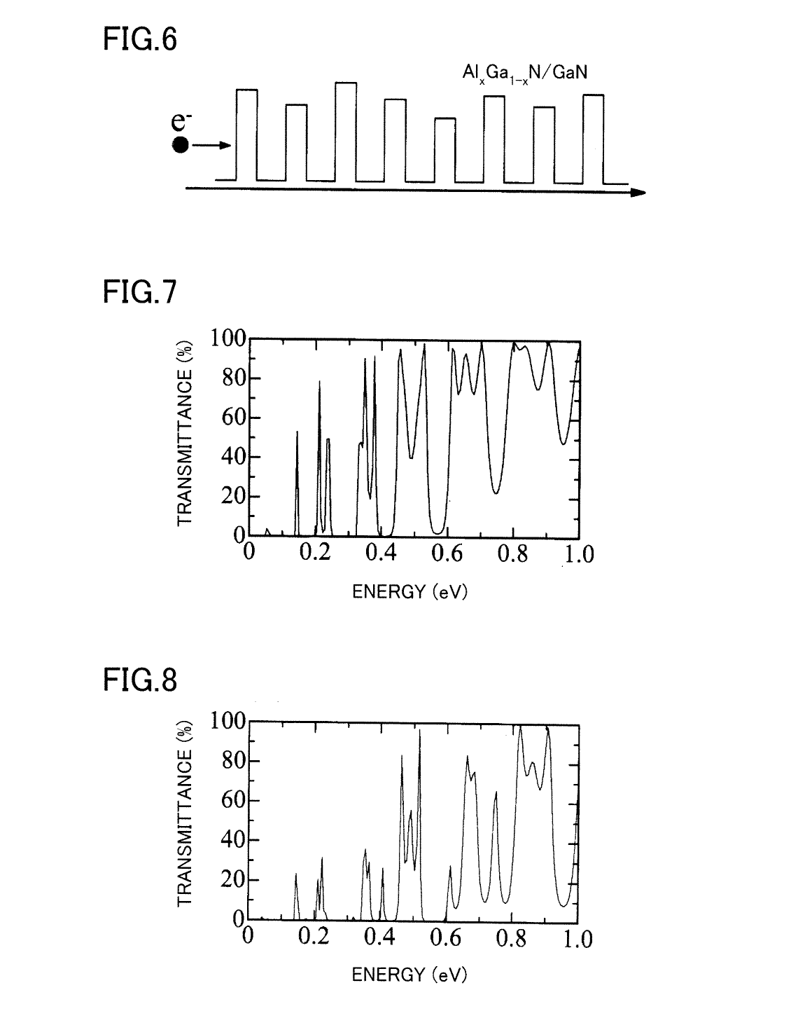

A result of calculating the electron wave transmittance of a randomized electron current reduction structure in which the periodicity of the MQB structure is intentionally broken will be described. FIG. 5 schematically illustrates the potential of the electron current reduction structure including the constituent layers with different thicknesses, and FIG. 6 schematically illustrates the potential of the electron current reduction structure including the constituent AlGaN layers with different Al contents. When the constituent layers have different thicknesses, the Al content in each of the AlGaN layers is fixed at 20%, and the AlGaN layers and the GaN layers have random thicknesses. The thickness of each of the constituent layers and the Al content in each of the AlGaN layers are limited as follows: the thickness is modulated within a range of ±1 nm, and when the total thickness of the constituent layers is 80 nm, the average Al content in the constituent layers is constantly 4%. When the constituent AlGaN layers have different Al contents, the thickness of each of the AlGaN layers and the thickness of each of the GaN layers are fixed at 2 nm and 8 nm, respectively, and the Al content in the AlGaN layer is modulated within a range of ±6%. Also in this case, when the total thickness of the constituent layers is 80 nm, the average Al content in the constituent layers is 4%. The reason why the average Al content is not changed is that the effect of reflection of electron waves can be more clearly understood.

FIG. 7 illustrates a result of calculating the electron wave transmittance of the electron current reduction structure including the constituent layers with different thicknesses, and FIG. 8 illustrates a result of calculating the electron wave transmittance of the electron current reduction structure including the constituent AlGaN layers with different Al contents. As illustrated in FIGS. 7 and 8, the transmittance of electron waves through a randomized electron current reduction structure model is significantly lower at energies near 0.2 eV than that of electron waves through a periodic MQB structure model. The reason for this is that the levels of the GaN layers are randomized by modulating the thicknesses or the Al content, and the levels of an adjacent pair of the GaN layers cannot be coupled together. Consequently, high reflectivity can be achieved at energies up to about 0.4 eV which is higher than 0.3 eV corresponding to the conduction band offset of AlGaN. This means that the randomized electron current reduction structure more effectively reduces electron current than a structure including the AlGaN layers having a uniform Al content. In particular, the electron current reduction structure model in which the Al contents are modulated can efficiently reduce transmission of electron waves at energies up to about 0.8 eV. This clearly shows that instead of a change in the composition of each of the GaN layers, a change in the composition of each of the AlGaN layers functioning as a barrier significantly affects a reduction in electron current.

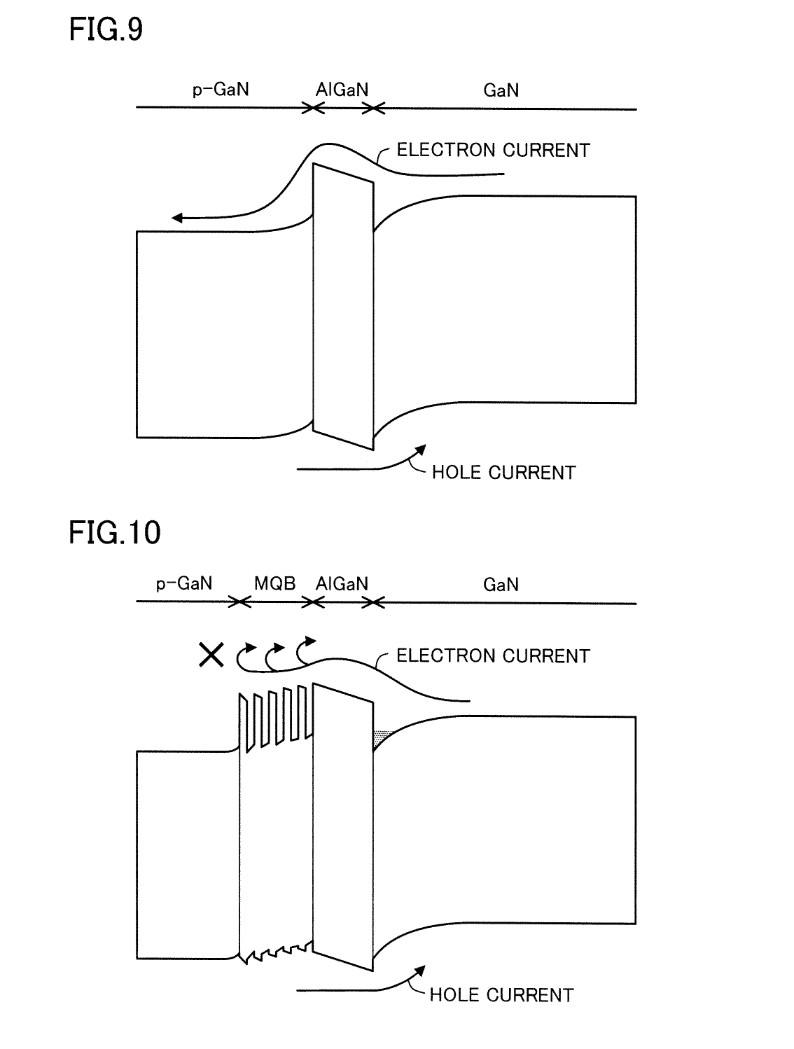

As illustrated in FIG. 9, when a p-type GaN layer is used as the gate of the GIT, not only hole current, but also electron current arising from the overflow of electrons flows. In contrast, when the MQB structure is formed between the p-type GaN layer and the AlGaN layer, hole current can be passed through the GIT as illustrated in FIG. 10, and the electron current arising from the overflow of electrons can be reduced, thereby reducing the loss of the nitride semiconductor transistor. The reason for this is that the MQB structure functions as an electron current reduction layer through which hole current is passed and which is configured to reduce electron current. Moreover, the effect of reflection of electron waves can be enhanced by using the electron current reduction structure showing broken periodicity as the electron current reduction layer, thereby enhancing the effect of reducing electron current. A specific structure of a nitride semiconductor transistor which is a GIT using an MQB structure and an electron current reduction layer of an electron current reduction structure will be described hereinafter.

### Embodiment

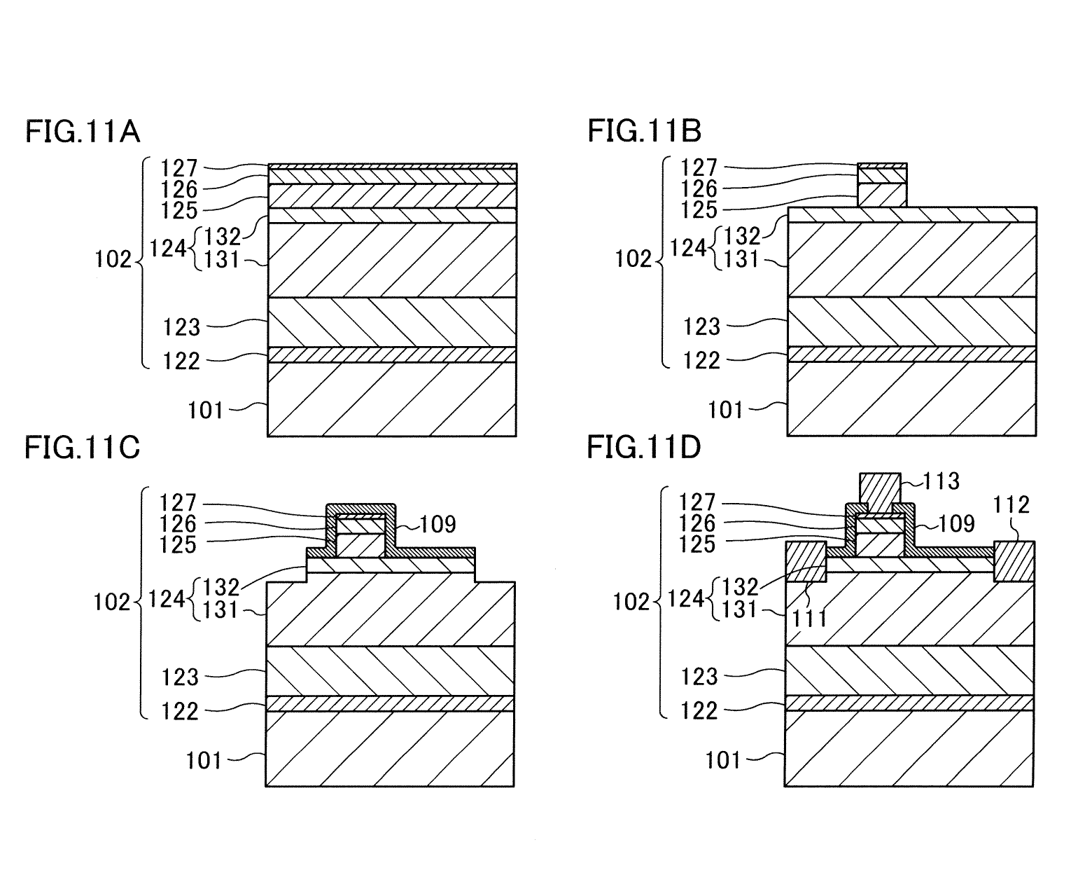

FIG. 11 sequentially illustrates process steps in an example method for fabricating a nitride semiconductor transistor. First, a nitride semiconductor layer 102 is formed on a substrate 101. The substrate 101 may be, for example, a silicon (Si) substrate having a principal surface which is the (111) plane. The nitride semiconductor layer 102 may be formed by crystal growth using metal organic chemical vapor deposition (MOCVD). In the crystal growth, trimethylaluminum ((CH₃)₃Al) may be used as the source material for Al, trimethylgallium ((CH₃)₃Ga) as the source material for Ga, and ammonia (NH₃) as the source material for N. Bis(cyclopentadienyl) magnesium (Cp₂Mg) may be used as a p-type dopant.

The nitride semiconductor layer 102 may include, e.g., a buffer layer 122, a superlattice layer 123, a heterojunction layer 124, an electron current reduction layer 125, a p-type layer 126, and a contact layer 127 which are sequentially formed on the substrate 101. The buffer layer 122 may be a 400-nm-thick AlN layer. The superlattice layer 123 may include 20-nm-thick GaN layers and 5-nm-thick AlN layers which are alternately formed over 40 cycles. The total thickness of the superlattice layer 123 may be 1 μm. The heterojunction layer 124 may be a multilayer structure including a 1-μm-thick undoped GaN layer 131 and an AlGaN layer 132 having an Al content of 25%. The electron current reduction layer 125 may be a multilayer structure of AlGaN layers and GaN layers. The AlGaN layers of the electron current reduction layer 125 preferably have random Al contents, and the AlGaN and GaN layers of the electron current reduction layer 125 preferably have random thicknesses. The Al contents and thicknesses may be, e.g., as illustrated in Table 1.

TABLE 1

| Al Content | Thickness |
|---|---|
| (%) | (nm) |
| 11 | 1.8 |
| 0 | 6 |
| 10 | 1.2 |
| 0 | 10 |
| 13 | 2 |
| 0 | 10 |
| 9 | 1.5 |
| 0 | 6 |
| 8 | 1 |
| 0 | 10 |
| 13 | 1.5 |
| 0 | 10 |
| 8 | 2 |
| 0 | 6 |
| 11 | 2.5 |
| 0 | 6 |
| 7 | 2 |
| 0 | 8 |
| 8 | 1.5 |
| 0 | 10 |
| 12 | 1 |

The thickness of the electron current reduction layer 125 is preferably 100 nm which is substantially identical with the electron coherence length. The constituent layers of the electron current reduction layer 125 may be doped with Mg which is a p-type impurity, and the doping concentration of Mg in each of the layers may be 2×10¹⁹ cm⁻³.

The p-type layer 126 may be a 100-nm-thick GaN layer, and may be doped with Mg to have a doping concentration of 1×10¹⁹ cm⁻³. The contact layer 127 may be a 6-nm-thick GaN layer, and may be doped with Mg to have a doping concentration higher than or equal to 1×10²⁰ cm⁻³.

Next, as illustrated in FIG. 11B, portions of p-type layers, i.e., the contact layer 127, the p-type layer 126, and the electron current reduction layer 125, are selectively removed by photolithography and chlorine-based dry etching. The conditions for the chlorine-based dry etching may be such that the flow rate of a chlorine gas is 30 sccm, the RF input power is 100 W, and the back pressure is 1 Pa. In this case, the etching rate is about 40 nm/min.

Next, as illustrated in FIG. 11C, a surface protection film 109 is formed, and recesses are formed in the heterojunction layer 124. The formation of the surface protection film 109 can reduce the surface level, and can provide stable device operation. The surface protection film 109 may be a 100-nm-thick SiN film, and may be formed by, thermal CVD. The conditions on which the SiN film is deposited may be such that the formation temperature of the SiN film is 700° C., and the flow rates of SiH₄ and NH₃ supplied are 2 sccm (cc/min, 1013 hPa, 0° C.) and 4 slm (1/min, 1013 hPa, 0° C.), respectively. The recesses may be formed in the heterojunction layer 124 by photolithography and chlorine-based dry etching. The etching depth may be about 40 nm in order to allow the recesses to extend below the interface between the AlGaN layer 132 and the GaN layer 131.

Next, as illustrated in FIG. 11D, electrodes are formed. First, a portion of the surface protection film 109 located on the contact layer 127 is removed by photolithography and wet etching using hydrohluoric acid. Subsequently, a gate electrode 113 is vapor-deposited on the contact layer 127. The gate electrode 113 may be Ni/Pt/Au making good ohmic contact with p-type GaN. Subsequently, source and drain electrodes 111 and 112 made of Ti/Au are formed in the recesses formed in the heterojunction layer 124 by vapor deposition.

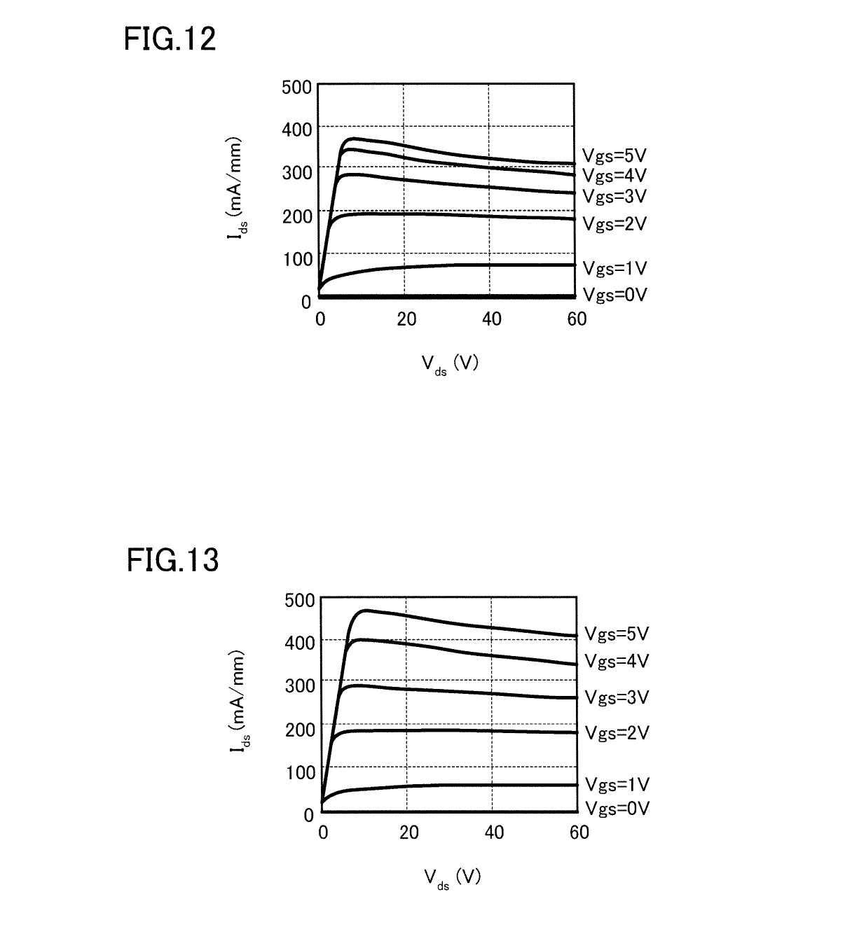

FIGS. 12 and 13 illustrate operating characteristics of a conventional nitride semiconductor transistor and a nitride semiconductor transistor including an electron current reduction layer, respectively. FIGS. 12 and 13 illustrate the relationship between the drain voltage Vds and the drain current Ids at various gate voltages Vgs. As illustrated in FIG. 12, when there is no electron current reduction layer, and the gate voltage Vgs is higher than or equal to 5 V, the drain current Ids tends to become saturated. A major factor which contributes to such a phenomenon is a loss arising from electron current flowing into the gate. In contrast, as illustrated in FIG. 13, the nitride semiconductor transistor including the electron current reduction layer can maintain high drain current Ids even with a gate voltage Vgs higher than or equal to 5 V. The reason for this is that the electron current reduction layer reduces electron current flowing into a gate electrode, resulting in an increase in current reaching a drain electrode.

As such, introduction of the electron current reduction layer can increase the drain current. Furthermore, the electron current reduction layer has an advantage that it can be formed only by changing the structures of layers foil ied by crystal growth, and a usual device formation process does not need to be changed.

The structures described in the embodiment are examples, and the structure of the nitride semiconductor layer and the structures of the electrodes may be appropriately changed. The substrate on which the nitride semiconductor layer is grown may be, e.g., a sapphire substrate or a silicon carbide substrate instead of a Si substrate.

While the electron current reduction layer is a multilayer structure of AlGaN layers and GaN layers, it may be a combination of a plurality of layers having different polarizations, and each containing at least one of Al, Ga, B, or In as a Group III element. The atomic radius of B is much smaller than that of any other Group III element; however, the band gap of BN is smaller than that of AlN, and thus, when the electron current reduction layer is made of a compound containing B, this allows greater flexibility in designing material properties. A nitride semiconductor containing In can advantageously reduce the band gap, and can advantageously increase the activation rate of p-type impurities. Therefore, when the GaN layer with a lower potential contains In, this can advantageously increase the activation rate of p-type impurities, and advantageously allows greater flexibility in designing a potential barrier. When B and In are contained in the electron current reduction layer, for example, triethylboron ((C₂H₅)₃B) and trimethylindium ((CH₃)₃In) can be used as source materials for B and In, respectively.

The nitride semiconductor transistor according to the present disclosure can reduce power loss, and is useful for, e.g., nitride semiconductor transistors driven at especially high current.

What is claimed is:

1. A nitride semiconductor transistor comprising:
a heterojunction layer including two or more nitride semiconductor layers having different polarizations;
a gate electrode disposed on the heterojunction layer; and
an electron current reduction layer disposed between the heterojunction layer and the gate electrode, having a p-type conductivity, and configured to pass hole current and reduce electron current.

2. The nitride semiconductor transistor of claim 1, wherein
the electron current reduction layer is a multilayer structure including a plurality of layers having different polarizations.

3. The nitride semiconductor transistor of claim 2, wherein
the plurality of layers are each made of a nitride semiconductor containing at least one of boron, aluminum, gallium, or indium.

4. The nitride semiconductor transistor of claim 2, wherein
the plurality of layers have random thicknesses.

5. The nitride semiconductor transistor of claim 1, further comprising:
a contact layer disposed between the electron current reduction layer and the gate electrode, and containing a higher concentration of a p-type impurity than other layers.

6. The nitride semiconductor transistor of claim 1, further comprising:
source and drain electrodes formed laterally outward of the gate electrode.

7. The nitride semiconductor transistor of claim 1, wherein
the heterojunction layer is disposed on a substrate, and
the substrate is a silicon substrate, a sapphire substrate, or a silicon carbide substrate.
